(19) United States
(12) Patent Application Publication
(10) Pub. No.: US 2026/0006971 A1
(43) Pub. Date: Jan. 1, 2026

(54) DISPLAY DEVICE, METHOD OF MANUFACTURING THE SAME AND ELECTRONIC DEVICE INCLUDING THE SAME

(71) Applicant: Samsung Display Co., LTD., Yongin-si (KR)

(72) Inventors: Kyung Rock SON, Yongin-si (KR); Sung Kook PARK, Yongin-si (KR); Jin Seok PARK, Yongin-si (KR); Moon Jung AN, Yongin-si (KR); Sang Hyun LEE, Yongin-si (KR); Jae Phil LEE, Yongin-si (KR)

(73) Assignee: Samsung Display Co., LTD., Yongin-si (KR)

(21) Appl. No.: 19/184,607

(22) Filed: Apr. 21, 2025

(30) Foreign Application Priority Data
Jun. 27, 2024 (KR) 10-2024-0084767

(51) Int. Cl. H10H 29/80; H10H 29/01; H10H 29/49

(52) U.S. Cl. CPC H10H 29/8325; H10H 29/012; H10H 29/032; H10H 29/49

(57) ABSTRACT

A display device includes a substrate and a display element layer disposed on the substrate. The display element layer includes: an anode electrode and a cathode electrode; a first reflective electrode disposed on the anode electrode; a second reflective electrode disposed on the cathode electrode; a light emitting element including a first protective electrode, a second protective electrode, a first element electrode disposed at an inner side of the first protective electrode, and a second element electrode disposed at an inner side of the second protective electrode; a first transparent electrode electrically connecting the first reflective electrode to the first protective electrode; and a second transparent electrode electrically connecting the second reflective electrode to the second protective electrode.

### CROSS-REFERENCE TO RELATED APPLICATION(S)

This application claims priority to and benefits of Korean patent application No. 10-2024-0084767 under 35 U.S.C. § 119, filed on Jun. 27, 2024 in the Korean Intellectual Property Office, the entire contents of which are incorporated herein by reference.

### BACKGROUND

### 1. Technical Field

Embodiments relate to a display device, a method of manufacturing a display device, and an electronic device including a display device.

### 2. Description of the Related Art

With the development of information technologies, the importance of a display device which is a connection medium between a user and information increases. Accordingly, display devices such as a liquid crystal display device, an organic light emitting display device, and an inorganic light emitting display device are increasingly used.

Some electrodes may be damaged in a transferring step of a light emitting element. A method of improving the light emission efficiency of the light emitting element while preventing damage of some electrodes may be required.

### SUMMARY

Embodiments provide a display device, a method of manufacturing a display device, and an electronic device including a display device, in which damage of electrodes of a light emitting element can be prevented.

However, embodiments are not limited to those set forth herein. The above and other embodiments will become more apparent to one of ordinary skill in the art to which the disclosure pertains by referencing the detailed description of the disclosure given below.

In accordance with an aspect of the disclosure, there is provided a display device including: a substrate; and a display element layer disposed on the substrate, wherein the display element layer includes: an anode electrode and a cathode electrode; a first reflective electrode disposed on the anode electrode; a second reflective electrode disposed on the cathode electrode; a light emitting element including a first protective electrode, a second protective electrode, a first element electrode disposed at an inner side of the first protective electrode, and a second element electrode disposed at an inner side of the second protective electrode; a first transparent electrode electrically connecting the first reflective electrode to the first protective electrode; and a second transparent electrode electrically connecting the second reflective electrode to the second protective electrode.

The first element electrode may be formed at side surfaces adjacent to the anode electrode among side surfaces of the light emitting element and a portion of a lower surface of the light emitting element, which is adjacent to the anode electrode. The second element electrode may be formed at side surfaces adjacent to the cathode electrode among the side surfaces of the light emitting element and a portion of the lower surface of the light emitting element, which is adjacent to the cathode electrode.

The first element electrode and the second element electrode may have a clamp shape.

The first protective electrode may be formed along side surfaces of the first element electrode and a lower surface of the first element electrode. The second protective electrode may be formed along side surfaces of the second element electrode and a lower surface of the second element electrode.

The first protective electrode and the second protective electrode may have a clamp shape.

The first element electrode and the second element electrode may include a same reflective conductive material. The first protective electrode and the second protective electrode may include a same conductive material.

The first element electrode and the second element electrode may include at least one of aluminum and titanium. The first protective electrode and the second protective electrode may include indium zinc oxide.

The first transparent electrode and the second transparent electrode may include a same transparent conductive material.

The display element layer may further include an overcoat layer partially covering the first reflective electrode and the second reflective electrode. The light emitting element may be disposed on the overcoat layer. In a cross-sectional view, a height of the first protective electrode may be smaller than a height of the first transparent electrode. Each of the height of the first protective electrode and the height of the first transparent electrode may be a height with respect to the overcoat layer in a cross-sectional view.

The display element layer may further include an overcoat layer partially covering the first reflective electrode and the second reflective electrode. The light emitting element may be disposed on the overcoat layer. In a cross-sectional view, an area in which the first element electrode is not in contact with the first protective electrode may be provided under the first element electrode.

In accordance with another aspect of the disclosure, there is provided a method of manufacturing a display device, the method including: manufacturing a pixel circuit layer disposed on a substrate; and manufacturing a display element layer on the pixel circuit layer, wherein the manufacturing of the display element layer includes: patterning an anode electrode and a cathode electrode on the pixel circuit layer; patterning a first reflective electrode electrically connected to the anode electrode and a second reflective electrode electrically connected to the cathode electrode; patterning an overcoat layer on the first reflective electrode and the second reflective electrode; and disposing, on the pixel circuit layer, a light emitting element including a protective layer, a first element electrode, and a second element electrode, and wherein the protective layer may be formed along side surfaces of the light emitting element and a lower surface of the light emitting element, and surround the first element electrode and the second element electrode.

The manufacturing of the display element layer may further include patterning a transparent electrode layer on the anode electrode, the first reflective electrode, the cathode electrode, the second reflective electrode, the overcoat layer, and the light emitting element.

The manufacturing of the display element layer may further include patterning a photoresist layer on the transparent electrode layer.

The manufacturing of the display element layer may further include: etching the transparent electrode layer and the protective layer, using the photoresist layer as an etching mask; providing the etched transparent electrode layer as a first transparent electrode and a second transparent electrode; and removing the photoresist layer.

The manufacturing of the display element layer may further include heat-treating in the display element layer. A heat-treatment temperature may be determined within a range in which the first and second transparent electrodes are crystallized and the protective layer is not crystallized.

The manufacturing of the display element layer may further include: etching the protective layer except a portion of the protective layer, which is surrounded by the heat-treated first and second transparent electrodes; and providing the etched protective layer as a first protective electrode and a second protective electrode.

The first protective electrode and the second protective electrode may have a clamp shape.

The first element electrode and the second element electrode may include a same reflective conductive material. The first protective electrode and the second protective electrode may include a same conductive material.

The first element electrode and the second element electrode may include at least one of aluminum and titanium. The first protective electrode and the second protective electrode may include indium zinc oxide.

The first transparent electrode and the second transparent electrode may include a same transparent conductive material.

In accordance with still another aspect of the disclosure, there is provided an electronic device including: a display device including a display element layer disposed on a substrate, wherein the display element layer may include: an anode electrode and a cathode electrode; a first reflective electrode disposed on the anode electrode; a second reflective electrode disposed on the cathode electrode; a light emitting element including a first semiconductor layer, a second semiconductor layer, and an insulative film; a first transparent electrode directly electrically connecting the second semiconductor layer to the first reflective electrode; and a second transparent electrode directly electrically connecting the first semiconductor layer to the second reflective electrode.

The electronic device may be at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that in case that an element is referred to as being “between” two elements, it can be the only element between the two elements, or one or more intervening elements may also be present. Like reference numerals refer to like elements throughout.

FIG. 1 is a block diagram illustrating an embodiment of a display device.

FIG. 2 is a block diagram illustrating an embodiment of any one of sub-pixels shown in FIG. 1.

FIG. 3 is a schematic plan view illustrating an embodiment of a display panel shown in FIG. 1.

FIG. 4 is a schematic cross-sectional view illustrating an embodiment of the display panel shown in FIG. 3.

FIG. 5 is a schematic cross-sectional view illustrating another embodiment of the display panel shown in FIG. 3.

FIG. 6 is a schematic plan view illustrating an embodiment of any one of pixels shown in FIG. 3.

FIG. 7 is a schematic cross-sectional view taken along line I-I′ shown in FIG. 6.

FIG. 8 is a schematic flowchart illustrating a method of manufacturing a display device in accordance with an embodiment.

FIG. 9 is a schematic flowchart illustrating a step of manufacturing a display element layer in accordance with an embodiment.

FIGS. 10 to 13 are schematic cross-sectional views illustrating process steps according to the step shown in FIG. 9.

FIG. 14 is a schematic flowchart illustrating a step of manufacturing first and second transparent electrodes in accordance with an embodiment.

FIGS. 15 to 19 are schematic cross-sectional views illustrating process steps according to the step shown in FIG. 14.

FIG. 20 is a block diagram illustrating an embodiment of a display system.

FIGS. 21 to 24 are schematic perspective views illustrating application examples of the display system shown in FIG. 20.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

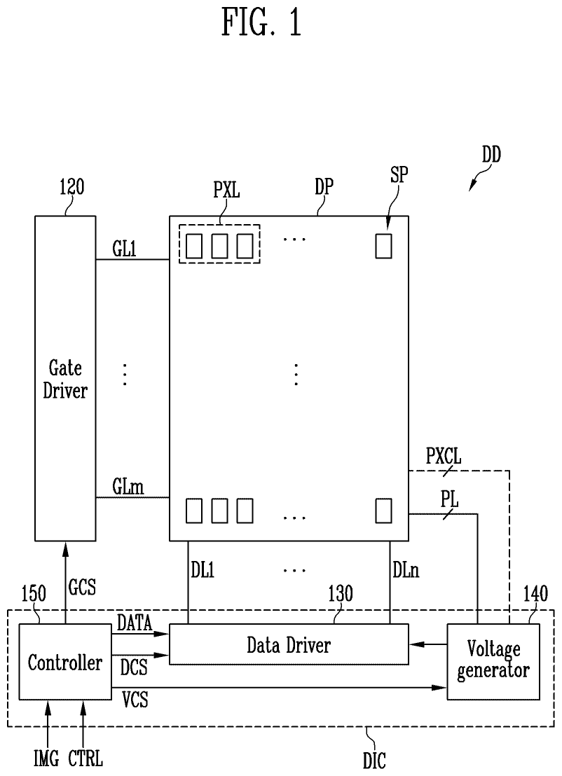

FIG. 1 is a block diagram illustrating an embodiment of a display device.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate lights of two or more colors. For example, each of the sub-pixels SP may generate lights of red, green, blue, cyan, magenta, yellow, white, and the like.

Two or more sub-pixels among the sub-pixels SP may constitute a pixel PXL. For example, the pixel PXL may include three sub-pixels as shown in FIG. 1. For example, the pixel PXL may emit lights of various colors with various luminances according to a combination of lights emitted from the sub-pixels included therein.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like.

The gate driver 120 may be disposed at a side of the display panel DP. However, embodiments are not limited thereto. For example, the gate driver 120 may be divided into two or more drivers which are physically and/or logically divided, and these drivers may be disposed at a side of the display panel DP and another side of the display panel DP, which is opposite to the side. For example, in some embodiments, the gate driver 120 may be disposed in various forms at the periphery of the display panel DP.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to n-th data lines DL1 to DLn by using the received voltages. In case that a gate signal is applied to each of the first to m-th gate lines GL1 to GLm, data signals corresponding to the image data DATA may be applied to the first to n-th data line DL1 to DLm. Accordingly, corresponding sub-pixels SP may generate light corresponding to the data signals. Accordingly, an image may be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate multiple voltages and provide the generated voltages to components of the display device DD. The voltage generator 140 may generate multiple voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

Besides, the voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a reference voltage may be applied to the first to n-th data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, it is illustrated that the pixel control lines PXCL are connected between the voltage generator 140 and the display panel DP. However, embodiments are not limited thereto. For example, the pixel control lines PXCL may be connected between the gate driver 120 and the display panel DP. The pixel control signals may be transferred to the sub-pixels SP from the gate driver 120 through the pixel control lines PXCL.

The controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on an integrated circuit (e.g., single integrated circuit). As shown in FIG. 1, the data driver 130, the voltage generator 140, and the controller 150 may be included in a driver integrated circuit DIC. The data driver 130, the voltage generator 140, and the controller 150 may be components functionally divided in a (single) driver integrated circuit DIC. In other embodiments, at least one of the data driver 130, the voltage generator 140, and the controller 150 may be provided as a component distinguished from the driver integrated circuit DIC.

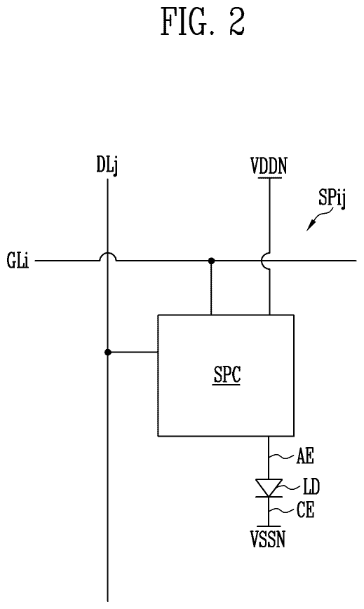

FIG. 2 is a block diagram illustrating an embodiment of any one of the sub-pixels shown in FIG. 1. In FIG. 2, a sub-pixel SPij arranged on an i-th row (i is an integer greater than or equal to 1 and smaller than or equal to m) and a j-th column (j is an integer greater than or equal to 1 and smaller than or equal to n) among the sub-pixels SP shown in FIG. 1 is illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL shown in FIG. 1, to receive a first power voltage. The second power voltage node VSSN may be connected to another of the power lines PL, to receive a second power voltage. The first power voltage may have a voltage level higher than a voltage level of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may emit light according to a current flowing from the anode electrode AE to the cathode electrode CE.

The sub-pixel circuit SPC may be connected to an i-th gate line GLi among the first to m-th gate lines GL1 to GLm shown in FIG. 1 and a j-th data line DLj among the first to n-th data lines DL1 to DLn shown in FIG. 1. In response to a gate signal received through the i-th gate line GLi, the sub-pixel circuit SPC may control the light emitting element LD to emit light according to a data signal received through the j-th data line DLj. In embodiments, the sub-pixel circuit SPC may be further connected to the pixel control lines PXCL shown in FIG. 1. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The transistors of the sub-pixel circuit SPC may include P-type transistors and/or N-type transistors. In embodiments, the transistors of the sub-pixel circuit SPC may include a Metal Oxide Silicon Field Effect Transistor (MOSFET). In embodiments, the transistors of the sub-pixel circuit SPC may include an amorphous silicon semiconductor, a monocrystalline silicon semiconductor, polycrystalline silicon semiconductor, an oxide semiconductor, and the like.

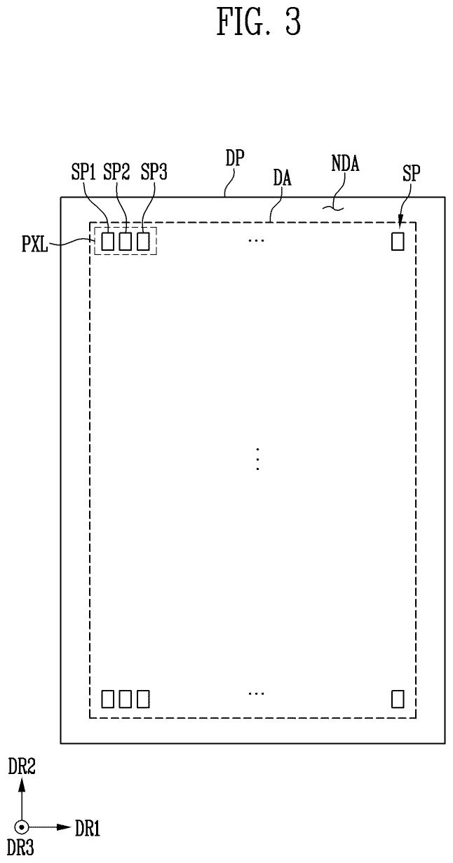

FIG. 3 is a schematic plan view illustrating an embodiment of the display panel shown in FIG. 1.

Referring to FIG. 3, a display panel DP may include a display area DA and a non-display area NDA. The display panel DP displays an image through the display area DA. The non-display area NDA may be disposed at the periphery of the display area DA.

The display panel DP may include sub-pixels SP in the display area DA. The sub-pixels SP may be arranged in a first direction DR1 and a second direction DR2 intersecting the first direction DR1. For example, the sub-pixels SP may be arranged in a matrix form along the first direction DR1 and the second direction DR2. In another example, the sub-pixels SP may be arranged in a zigzag form along the first direction DR1 and the second direction DR2. The arrangement of the sub-pixels SP may vary in some embodiments. The first direction DR1 may be a row direction, and the second direction DR2 may be a column direction.

Two or more sub-pixels among the sub-pixels SP may constitute a pixel (e.g., single pixel) PXL. In FIG. 3, it is illustrated that the pixel PXL includes three sub-pixels SP1 to SP3. However, embodiments are not limited thereto. For example, the pixel PXL may include two sub-pixels. Hereinafter, for convenience of description, it is assumed that the pixel PXL includes first to third sub-pixels SP1 to SP3.

Each of the first to third sub-pixels SP1 to SP3 may generate light of one of various colors such as red, green, blue, cyan, magenta, and yellow. Hereinafter, for clear and simple description, it is assumed that the first sub-pixel SP1 generates light of a red color, the second sub-pixel SP2 generates light of a green color, and the third sub-pixel SP3 generates light of a blue color.

Each of the first to third sub-pixels SP1 to SP3 may include at least one light emitting element that generates light. In embodiments, light emitting elements of the first to third sub-pixels SP1 to SP3 may generate light of the same color. For example, the light emitting elements of the first to third sub-pixels SP1 to SP3 may generate light of a blue color. In other embodiments, the light emitting elements of the first to third sub-pixels SP1 to SP3 may generate lights of different colors. For example, the light emitting elements of the first to third sub-pixels SP1 to SP3 may generate lights a red color, a green color, and a blue color, respectively.

Self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines connected to the sub-pixels SP, e.g., the first to m-th gate lines GL1 to GLm, the first to n-th data lines DL1 to DLn, the power lines PL, and the pixel control lines PXCL, which are shown in FIG. 1, may be disposed in the non-display area NDA.

At least one of the gate driver 120, the data driver 130, the voltage generator 140, and the controller 150, which are shown in FIG. 1, may be disposed in the non-display area NDA of the display panel DP. In embodiments, the gate driver 120 may be disposed in the non-display area NDA. The data driver 150, the voltage generator 140, and the controller 150 may be implemented into the driver integrated circuit DIC shown in FIG. 1, which is distinguished from the display panel DP, and the driver integrated circuit DIC may be connected to the lines disposed in the non-display area NDA. In other embodiments, the gate driver 120, the data driver 130, the voltage generator 140, and the controller 150 may be implemented into an integrated circuit distinguished from the display panel DP.

In embodiments, the display area DA may have various shapes. The display area DA may have a closed-loop shape including linear sides and/or curved sides. For example, the display area DA may have shapes such as a polygon, a circle, a semicircle, and an ellipse.

In embodiments, the display panel DP may have a flat display surface. In other embodiments, the display panel DP may at least partially have a round display surface. In embodiments, the display panel DP may be bendable, foldable or rollable. The display panel DP and/or a substrate of the display panel DP may include materials having flexibility.

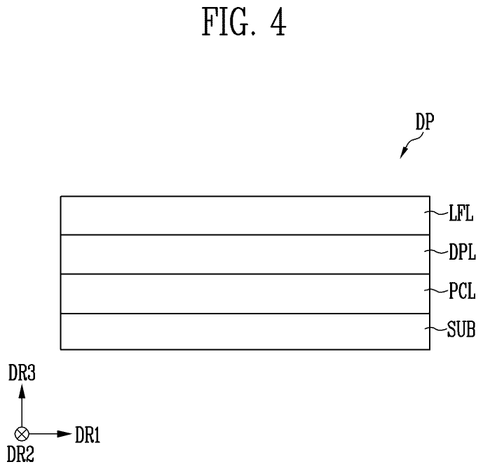

FIG. 4 is a schematic cross-sectional view illustrating an embodiment of the display panel shown in FIG. 3.

Referring to FIG. 4, a display panel DP may include a substrate SUB, and a pixel circuit layer PCL, a display element layer DPL, and a light functional layer LFL, which are sequentially stacked in a third direction DR3 intersecting the first and second directions DR1 and DR2 on the substrate SUB.

The substrate SUB may be made of an insulative material such as glass or resin. For example, the substrate SUB may include a glass substrate. In another example, the substrate SUB may include polyimide (PI) substrate. In still another example, the substrate SUB may include a silicon wafer substrate formed using a semiconductor process.

In embodiments, the substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, n polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may function as circuit elements, lines, and the like.

The circuit elements of the pixel circuit layer PCL may constitute a sub-pixel circuit SPC of each of the sub-pixels SP shown in FIG. 3. For example, the circuit elements of the pixel circuit layer PCL may be provided as transistors and one or more capacitors of the sub-pixel circuit SPC.

The lines of the pixel circuit layer PCL may include lines connected to each of the sub-pixels SP. The lines of the pixel circuit layer PCL may include various signal lines and/or various voltage lines, which are necessary for driving the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or light scattering particles. For example, color conversion particles may include quantum dots. The quantum dots may change a wavelength (or color) of light emitted from the display element layer DPL. The light functional layer LFL may further include light scattering patterns having light scattering particles. In embodiments, the light conversion patterns and the light scattering patterns may be omitted.

The light functional layer LFL may further include a color filter layer including color filters. The color filter may allow light having a specific wavelength (or specific color) to be selectively transmitted therethrough. In embodiments, the color filter layer may be omitted.

A window for protecting an exposed surface (or top/upper surface) of the display panel DP may be provided on the light functional layer LFL. The window may protect the display panel DP from external impact. The window may be bonded to the light functional layer LFL through an optically transparent adhesive (or cohesive) member. The window may have a multi-layer structure selected from a glass substrate, a plastic film, and a plastic substrate. This multi-layer structure may be formed by a continuous process or an adhesive process using an adhesive layer. The whole or a portion of the window may have flexibility.

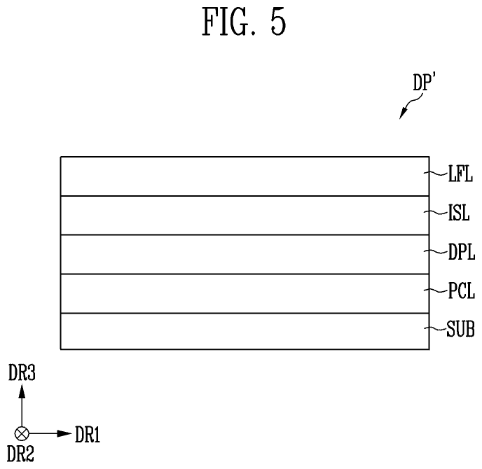

FIG. 5 is a schematic cross-sectional view illustrating another embodiment of the display panel shown in FIG. 3.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be formed in an identical or similar manner as the substrate SUB, the pixel circuit layer PCL, the display element layer DPL, and the light functional layer LFL, which are described with reference to FIG. 4, respectively. Hereinafter, redundant descriptions will be omitted.

The input sensing layer ISL may sense a user input with respect to a top surface (or display surface) of the display panel DP′. The input sensing layer ISL may include components suitable for sensing an external object such as a hand of a user or a pen. For example, the input sensing layer ISL may include touch electrodes.

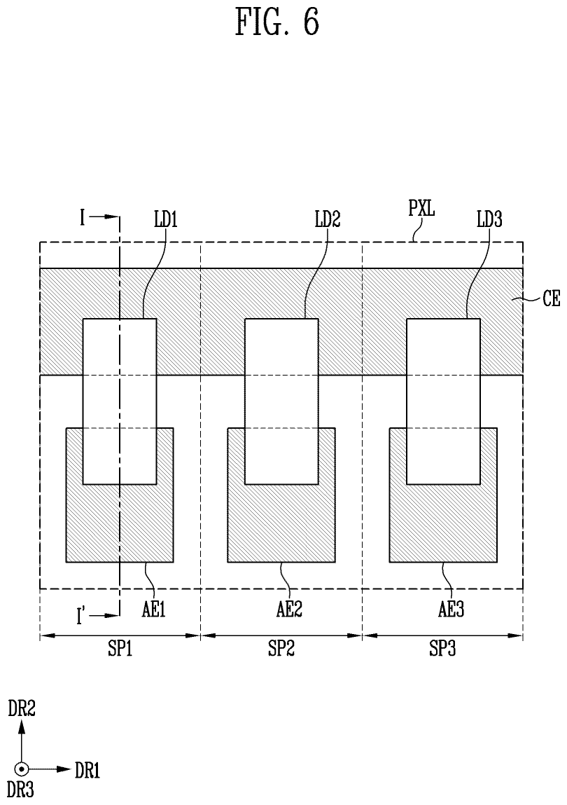

FIG. 6 is a schematic plan view illustrating an embodiment of any one of the pixels shown in FIG. 3.

Referring to FIG. 6, a pixel PXL may include first to third sub-pixels SP1 to SP3. The first to third sub-pixels SP1 to SP3 may be arranged in the first direction DR1. However, the arrangement of the pixel PXL is not limited thereto, and may be variously changed in some embodiments. For example, the first to third sub-pixels SP1 to SP3 may be arranged in a zigzag form.

First to third anode electrodes AE1 to AE3 may be disposed in the first to third sub-pixels SP1 to SP3, respectively. The first anode electrode AE1 may be provided as an anode electrode AE (see FIG. 2) connected to a sub-pixel circuit SPC (see FIG. 2) of the first sub-pixel SP1. The second anode electrode AE2 may be provided as an anode electrode AE connected to a sub-pixel circuit SPC of the second sub-pixel SP2. The third anode electrode AE3 may be provided as an anode electrode AE connected to a sub-pixel circuit SPC of the third sub-pixel SP3.

A cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in the second direction DR2. In embodiments, the cathode electrode CE may extend in the first direction DR1, to be used as a common electrode of the pixel PXL and other pixels adjacent to the pixel PXL. For example, the cathode electrode CE may extend in the second direction DR2 in addition to the first direction DR1, to be used as a common electrode of all the sub-pixels SP shown in FIG. 3. For example, the cathode electrode CE may have various shapes. In embodiments, the first to third anode electrodes AE1 to AE3 and the cathode electrode CE may include the same conductive material.

First to third light emitting elements LD1 to LD3 may be disposed on the first to third anode electrodes AE1 to AE3 and the cathode electrode CE. The first light emitting element LD1 may be electrically connected to the first anode electrode AE1 and the cathode electrode CE. The first light emitting element LD1 may be provided as a light emitting element LD (see FIG. 2) connected to the sub-pixel circuit SPC of the first sub-pixel SP1. The second light emitting element LD2 may be electrically connected to the second anode electrode AE2 and the cathode electrode CE. The second light emitting element LD2 may be provided as a light emitting element LD connected to the sub-pixel circuit SPC of the second sub-pixel SP2. The third light emitting element LD3 may be electrically connected to the third anode electrode AE3 and the cathode electrode CE. The third light emitting element LD3 may be provided as a light emitting element LD connected to the sub-pixel circuit SPC of the third sub-pixel SP3.

The first light emitting element LD1, the second light emitting element LD2, and the third light emitting element LD3 may be inorganic light emitting diodes including an inorganic light emitting material. However, embodiments are not limited thereto. For example, organic light emitting diodes may be used.

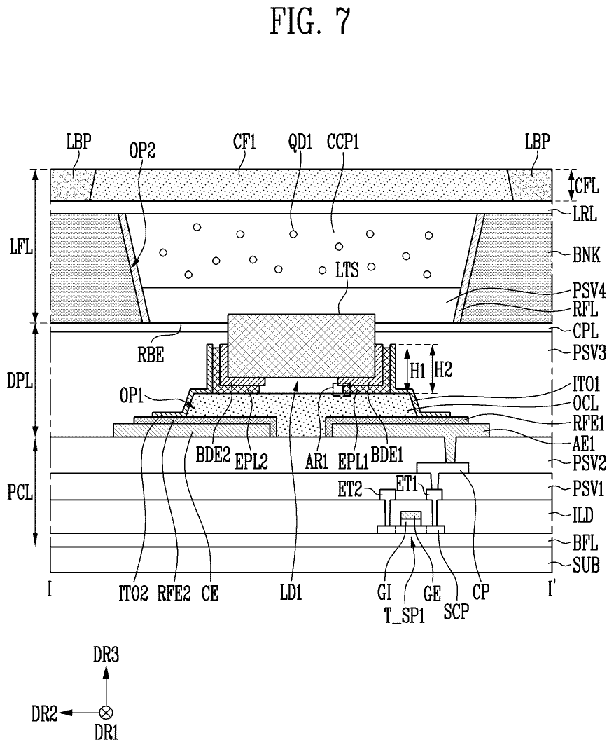

FIG. 7 is a schematic cross-sectional view taken along line I-I′ shown in FIG. 6.

Referring to FIGS. 6 and 7, a pixel circuit layer PCL, a display element layer DPL, and a light functional layer LFL may be sequentially disposed on a substrate SUB.

Sub-pixel circuits respectively corresponding to the first to third sub-pixels SP1 to SP3 may be provided in the pixel circuit layer PCL.

As described with reference to FIG. 2, the sub-pixel circuit SPC (see FIG. 2) of each of the first to third sub-pixels SP1 to SP3 may include transistors and one or more capacitors. Semiconductor patterns and conductive patterns of the pixel circuit layer PCL may function as the transistors and the capacitors of the sub-pixel circuit SPC. For example, the conductive patterns of the pixel circuit layer PCL may further function as lines, e.g., the first to m-th gate lines GL1 to GLm, the first to n-th data lines DL1 to DLn, the power lines PL, and the pixel control lines PXCL, which are shown in FIG. 1.

The pixel circuit layer PCL may include a buffer layer BFL, at least one interlayer insulating layer ILD, a first passivation layer PSV1, and a second passivation layer PSV2.

The buffer layer BFL may be disposed on a surface of the substrate SUB. The buffer layer BFL may prevent an impurity from being diffused or permeated into circuit elements and lines, which are included in the pixel circuit layer PCL. The buffer layer BFL may include an inorganic insulating layer including an inorganic material. In embodiments, the buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer or a multi-layer. In case that the buffer layer BFL is provided as the multi-layer, layers of the multi-layer may be formed of the same material or be formed of different materials.

In embodiments, one or more barrier layers may be disposed between the substrate SUB and the buffer layer BFL. Each of the barrier layers may include polyimide.

A transistor T_SP1 may be disposed on the buffer layer BFL. The transistor T_SP1 may be any one of the transistors of the sub-pixel circuit SPC included in the first sub-pixel SP1. For example, the transistor T_SP1 may be understood as a transistor connected to a first anode electrode AE1 among the transistors of the sub-pixel circuit SPC.

The transistor T_SP1 may include a semiconductor pattern SCP, a gate electrode GE, a first terminal ET1, and a second terminal ET2. The first terminal ET1 may be any one of a source electrode and a drain electrode, and the second terminal ET2 may be the other of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact region in contact with the first terminal ET1 and a second contact region in contact with the second terminal ET2. A region between the first contact region and the second contact region may be a channel region. The channel region may overlap the gate electrode GE of the transistor T_SP1. The channel region may be a semiconductor pattern undoped with an impurity, and may be an intrinsic semiconductor. Each of the first contact region and the second contact region may be a semiconductor pattern doped with the impurity. For example, a p-type impurity may be used as the impurity, but embodiments are not limited thereto.

The semiconductor pattern SCP may include any one of various types of semiconductors, e.g., any one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may be inorganic insulating layers including an inorganic material. For example, each of the interlayer insulating layers ILD may include at least one of silicon nitride (SiNₓ), silicon oxide (SiOₓ), silicon oxynitride (SiOₓN_{y}), and a metal oxide such as aluminum oxide (AlOₓ). However, the interlayer insulating layers ILD are not limited thereto. For example, any one of the interlayer insulating layers ILD may include an organic insulating layer including an organic material.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be provided (e.g., entirely provided) on the semiconductor pattern SCP and the buffer layer BFL, to cover the semiconductor pattern SCP and the buffer layer BFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP. The gate electrode GE may be provided as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided as a multi-layer including at least one material among molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be in contact with the first and second contact regions of the semiconductor pattern SCP, respectively. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are illustrated as individual electrodes electrically connected to the semiconductor pattern SCP, embodiments are not limited thereto. In embodiments, the first terminal ET1 may be the first contact region adjacent to a side of the channel region of the semiconductor pattern SCP, and the second terminal ET2 may be the second contact region adjacent to the other side of the channel region of the semiconductor pattern SCP. The first terminal ET1 may be electrically connected to a light emitting element LD through a connection means such as a bridge electrode, which is disposed on at least one of the interlayer insulating layers ILD.

In embodiments, the transistor T_SP1 may be formed as a low temperature poly-silicon transistor. However, embodiments are not limited thereto. For example, the transistor T_SP1 may be formed as an oxide semiconductor transistor. In embodiments, the sub-pixel circuit of the first sub-pixel SP1 may include different types of transistors. For example, the transistor T_SP1 may be formed as a low temperature poly-silicon transistor, and another transistor of the first sub-pixel SP1 may be formed as an oxide semiconductor transistor. An oxide semiconductor of the corresponding oxide semiconductor transistor may be disposed on any one of the interlayer insulating layers ILD instead of an insulating layer on which the semiconductor pattern SCP of the transistor T_SP1 is disposed.

In embodiments, a case where the transistor T_SP1 is a transistor having a top gate structure is described as an example. However, embodiments are not limited thereto. For example, the transistor T_SP1 may be a transistor having a bottom gate structure. For example, the structure of the transistor T_SP1 may be variously changed.

At least some of various lines of the display panel DP and/or the display device DD may be further disposed on the interlayer insulating layers ILD.

The first passivation layer PSV1 may be disposed over the interlayer insulating layers ILD and the first and second terminals ET1 and ET2. A passivation layer may be designated as a protective layer or a via layer. The first passivation layer PSV1 may protect components disposed thereunder, and provide a flat top surface (or flat upper surface).

A connection pattern CP may be disposed on the first passivation layer PSV1. The connection pattern CP may be connected to the first terminal ET1 of the transistor T_SP1 while penetrating the first passivation layer PSV1. The connection pattern CP may include at least one material among copper (Cu), molybdenum (Mo), tungsten (W), aluminum neodymium (AlNd), titanium (Ti), aluminum (Al), and silver (Ag).

At least some of various lines of the display panel DP and/or the display device DD may be further disposed on the first passivation layer PSV1.

The second passivation layer PSV2 may be disposed over the connection pattern CP and the first passivation layer PSV1. The second passivation layer PSV2 may protect components disposed thereunder, and provide a flat top surface (or flat upper surface).

Each of the first and second passivation layers PSV1 and PSV2 may include an inorganic insulating layer including an inorganic material and/or an organic insulating layer including an organic material. The inorganic insulating layer may include, for example, at least one of silicon oxide (SiOₓ), silicon nitride (SiNₓ), silicon oxynitride (SiOₓN_{y}), and a metal oxide such as aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first and second passivation layers PSV1 and PSV2 and any one of the interlayer insulating layers ILD may include the same material, but embodiments are not limited thereto. Each of the first and second passivation layers PSV1 and PSV2 may be provided (or formed) as a single layer, but be provided (or formed) as a multi-layer.

The display element layer DPL may be disposed on the second passivation layer PSV2. The display element layer DPL may include the first anode electrode AE1, a cathode electrode CE, first and second reflective electrodes RFE1 and RFE2, a first light emitting element LD1, an overcoat layer OCL, a third passivation layer PSV3, and a capping layer CPL.

The first anode electrode AE1 and the cathode electrode CE may be disposed on the pixel circuit layer PCL. For example, the first anode electrode AE1 and the cathode electrode CE may be disposed on the second passivation layer PSV2.

The first anode electrode AE1 may be electrically connected to the connection pattern CP through a contact hole penetrating the second passivation layer PSV2. For example, the first anode electrode AE1 may be electrically connected to the transistor T_SP1.

The cathode electrode CE may be spaced apart from the first anode electrode AE1 in the second direction DR2. The cathode electrode CE may be electrically connected to the second power voltage node VSSN shown in FIG. 2. Accordingly, the second power voltage applied to the second power voltage node VSSN may be transferred to the cathode electrode CE.

The first reflective electrode RFE1 may be disposed on the first anode electrode AE1. For example, the first reflective electrode REFI may be disposed on a side surface of the first anode electrode AE1.

The second reflective electrode RFE2 may be disposed on the cathode electrode CE. For example, the second reflective electrode RFE2 may be disposed on a side surface of the cathode electrode CE.

The first and second reflective electrodes RFE1 and RFE2 may include conductive materials suitable for reflecting light. Accordingly, the light output efficiency of the first light emitting element LD1 may be improved. The first and second reflective electrodes RFE1 and RFE2 may include the same reflective conductive material. In embodiments, the first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

The overcoat layer OCL may be disposed a first opening OP1 in which the first and second reflective electrodes RFE1 and RFE2 and the first light emitting element LD1 are disposed. The overcoat layer OCL may partially cover the first and second reflective electrodes RFE1 and RFE2.

The first light emitting LD1 may be disposed on the overcoat layer OCL. The overcoat layer OCL may fix the first light emitting element LD1 not to move.

For example, the overcoat layer OCL may protect components disposed thereunder from a foreign matter such as dust or moisture. For example, the overcoat layer OCL may include at least one of an inorganic insulating layer and an organic insulating layer. For example, the overcoat layer OCL may include epoxy, but embodiments are not limited thereto.

The first light emitting element LD1 may include first and second element electrodes BDE1 and BDE2 facing in the same direction (e.g., the opposite direction of the third direction DR3).

The first and second element electrodes BDE1 and BDE2 may be spaced apart from each other in the second direction DR2. The first element electrode BDE1 may be disposed adjacent to the first anode electrode AE1, and the second element electrode BDE2 may be disposed adjacent to the cathode electrode CE.

The first and second element electrodes BDE1 and BDE2 may include conductive materials suitable for reflecting light. Accordingly, the light output efficiency of the first light emitting element LD1 may be improved. The first and second element electrodes BDE1 and BDE2 may include the same reflective conductive material. In embodiments, the first and second element electrodes BDE1 and BDE2 may include at least one of aluminum (Al), titanium (Ti), and alloys thereof. However, embodiments are not limited thereto.

The first element electrode BDE1 may be formed along side surfaces adjacent to the first anode electrode AE1 among side surfaces of the first light emitting element LD1. For example, the first element electrode BDE1 may be formed at a portion of a bottom surface (or lower surface) of the first light emitting element LD1, which is adjacent to the first anode electrode AE1. The first element electrode BDE1 may not be disposed on a top surface (or upper surface) LTS of the first light emitting element LD1. For example, the first element electrode BDE1 may have a clamp shape.

The first element electrode BDE1 may be electrically connected to a first semiconductor layer included in the first light emitting element LD1. The first semiconductor layer may include, for example, at least one p-type semiconductor layer. For example, the first semiconductor layer may include at least one semiconductor material among gallium nitride (GaN), aluminum gallium nitride (AlGaN), indium gallium nitride (InGaN), aluminum nitride (AlN), and indium nitride (InN), and be a p-type semiconductor layer doped with a second conductive dopant (or p-type dopant) such as magnesium (Mg), zinc (Zn), calcium (Ca), strontium (Sr) or barium (Ba). However, the material constituting the first semiconductor layer is not limited thereto, and various materials may constitute the first semiconductor layer. In an embodiment, the first semiconductor layer may include a gallium nitride (GaN) semiconductor material doped with the second conductive dopant (or p-type dopant).

The second element electrode BDE2 may be formed along side surfaces adjacent to the cathode electrode CE among the side surfaces of the first light emitting element LD1. For example, the second element electrode BDE2 may be formed at a portion of the bottom surface (or lower surface) of the first light emitting element LD1, which is adjacent to the cathode electrode CE. The second element electrode BDE2 may not be disposed on the top surface (or upper surface) LTS of the first light emitting element LD1. For example, the second element electrode BDE2 may have a clamp shape.

The second element electrode BDE2 may be connected to a second semiconductor layer included in the first light emitting element LD1. The second semiconductor layer may include, for example, at least one n-type semiconductor layer. For example, the second semiconductor layer may include any one semiconductor material among gallium nitride (GaN), aluminum gallium nitride (AlGaN), indium gallium nitride (InGaN), aluminum nitride (AlN), and indium nitride (InN), and be an n-type semiconductor layer doped with a first conductive dopant (or n-type dopant) such as silicon (Si), germanium (Ge) or tin (Sn). However, the material constituting the second semiconductor layer is not limited thereto, and various materials may constitute the second semiconductor layer. In an embodiment, the second semiconductor layer may include a gallium nitride (GaN) semiconductor material doped with the first conductive dopant (or n-type dopant).

For example, the first light emitting element LD1 may include first and second protective electrodes EPL1 and EPL2 facing in the same direction (e.g., the opposite direction of the third direction DR3).

The first and second protective electrodes EPL1 and EPL2 may be spaced apart from each other in the second direction DR2. The first protective electrode EPL1 may be disposed adjacent to the first anode electrode AE1, and the second protective electrode EPL2 may be disposed adjacent to the cathode electrode CE.

The first protective electrode EPL1 may be formed along side surfaces of the first element electrode BDE1 and a bottom surface (or lower surface) of the first element electrode BDE1. For example, the first protective electrode EPL1 may have a clamp shape. The first element electrode BDE1 may be disposed at an inner side of the first protective electrode EPL1.

In embodiments, the first protective electrode EPL1 may be disposed at an exposed portion of the first element electrode BDE1.

The second protective electrode EPL2 may be formed along side surfaces of the second element electrode BDE2 and a bottom surface (or lower surface) of the second element electrode BDE2. For example, the second protective electrode EPL2 may have a clamp shape. The second element electrode BDE2 may be disposed at an inner side of the second protective electrode EPL2.

In embodiments, the second protective electrode EPL2 may be disposed at an exposed portion of the second element electrode BDE2.

As the first element electrode BDE1 is disposed at the inner side of the first protective electrode EPL1 and the second element electrode BDE2 is disposed at the inner side of the second protective electrode EPL2, the first and second protective electrodes EPL1 and EPL2 may protect the first and second element electrodes BDE1 and BDE2 from an external cleaning solution in a transferring process of the first light emitting element LD1. Accordingly, the first and second element electrodes BDE1 and BDE2 may be manufactured not only using material which are not damaged by the external cleaning solution, such as gold (Au) and chromium (Cr), but also using material such as titanium (Ti) and aluminum (Al).

Titanium (Ti) and aluminum (Al) may have a reflectivity higher than a reflectivity of gold (Au) and chromium (Cr). Accordingly, the first and second element electrodes BDE1 and BDE2 manufactured using titanium (Ti) and aluminum (Al) reflect upwardly (in the third direction DR3) light of the first light emitting element LD1, which is emitted downwardly (in the opposite direction of the third direction DR3), thereby increasing the luminance of the display device DD. For example, since titanium (Ti) and aluminum (Al) are cheaper than gold (Au), manufacturing cost of the first light emitting element LD1 may be reduced.

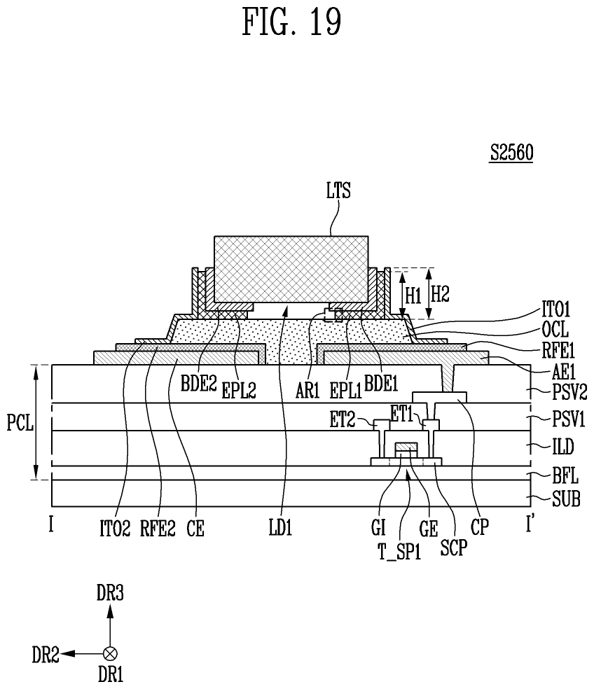

In embodiments, as the first protective electrode EPL disposed under the first element electrode BDE1 is etched, an area AR1 may be provided, in which the first element electrode BDE1 and the first protective electrode EPL1 are not in contact with each other. For example, the first area AR1 may be provided between the first element electrode BDE1 and the overcoat layer OCL. For example, an area may be provided, in which the second element electrode BDE2 and the second protective electrode EPL2 are not in contact with each other. This will be described in more detail later together with FIG. 19.

In embodiments, the first and second protective electrodes EPL1 and EPL2 may be disposed in the same display element layer DPL, and include the same conductive material. In embodiments, the first and second protective electrodes EPL1 and EPL2 may include a conductive metal oxide such as indium zinc oxide (IZO). However, the material of the first and second protective electrodes EPL1 and EPL2 is not limited thereto.

A first transparent electrode ITO1 may electrically connect the first reflective electrode RFE1 to the first protective electrode EPL1. Accordingly, the first element electrode BDE1 may be electrically connected to the first anode electrode AE1 through the first protective electrode EPL1, the first transparent electrode ITO1, and the first reflective electrode RFE1.

The first transparent electrode ITO1 may be disposed at an exposed portion of the first protective electrode EPL1, an exposed portion of the overcoat layer OCL, and an exposed portion of the first reflective electrode RFE1.

A second transparent electrode ITO2 may electrically connect the second reflective electrode RFE2 to the second protective electrode EPL2. Accordingly, the second element electrode BDE2 may be electrically connected to the cathode electrode CE through the second protective electrode EPL2, the second transparent electrode ITO2, and the second reflective electrode RFE2.

The second transparent electrode ITO2 may be disposed at an exposed portion of the second protective electrode EPL2, an exposed portion of the overcoat layer OCL, and an exposed portion of the second reflective electrode RFE2.

In embodiments, the first and second transparent electrodes ITO1 and ITO2 may be formed substantially transparent or translucent to satisfy a certain light transmittance. The first transparent electrode ITO1 and the second transparent electrode ITO2 may be disposed in the same display element layer DPL, and include the same transparent conductive material. In embodiments, the first and second transparent electrodes ITO1 and ITO2 may include at least one of various transparent conductive materials such as indium tin oxide (ITO), zinc oxide (ZnO), indium gallium zinc oxide (IGZO), and indium tin zinc oxide (ITZO). However, the material of the first and second transparent electrodes ITO1 and ITO2 is not limited thereto.

In a cross-sectional view, a height H1 of the first protective electrode EPL1 may be smaller than a height H2 of the first transparent electrode ITO1. Each of the height H1 of the first protective electrode EPL1 and the height H2 of the first transparent electrode ITO1 may be a height with respect to the overcoat layer OCL in a cross-sectional view. The height H1 of the first protective electrode EPL1 and the height H2 of the first transparent electrode ITO1 will be described in more detail later together with FIG. 19.

The third passivation layer PSV3 may be disposed over the first and second transparent electrodes ITO1 and ITO2. The third passivation layer PSV3 may protect components disposed thereunder, and provide a flat top surface (or flat upper surface). The third passivation layer PSV3 and any one of the first and second passivation layers PSV1 and PSV2 may include the same material, but embodiments are not limited thereto.

In embodiments, the third passivation layer PSV3 may not be disposed on the top surface (or upper surface) LTS of the first light emitting element LD1. The first light emitting element LD1 may protrude to the light functional layer LFL. The first light emitting element LD1 may be at least partially disposed in a second opening OP2 of a bank BNK. For example, a height of the top surface (or upper surface) LTS of the first light emitting element LD1 from the substrate SUB may be higher than a height of a lowermost end RBE of a reflective layer RFL from the substrate SUB. Accordingly, light emitted from the first light emitting element LD1 may be provided to the light functional layer LFL at a relatively high ratio.

The capping layer CPL may be disposed on the third passivation layer PSV3. The capping layer CPL may protect components disposed under the capping layer CPL, such as the first light emitting element LD1, from external moisture, humidity, and the like. In embodiments, the capping layer CPL may not be disposed on a top surface (or upper surface) of the first light emitting element LD1. In other embodiments, the capping layer CPL may cover (e.g., entirely cover) the first light emitting element LD1 and the third passivation layer PSV3. The capping layer CPL may include at least one of silicon nitride (SiNₓ), silicon oxide (SiOₓ), silicon oxynitride (SiOₓN_{y}), and a metal oxide such as aluminum oxide (AlOₓ). However, the material of the capping layer CPL is not limited thereto.

In the above, the pixel circuit layer PCL and the display element layer DPL of the first sub-pixel SP1 have been described. Each of the second and third sub-pixels SP2 and SP3 shown in FIG. 6 may also be formed in an identical or similar manner as the first sub-pixel SP1 within a range in which it is not differently described herein.

The light functional layer LFL may be disposed on the capping layer CPL. The light functional layer LFL may include the BNK, the reflective layer RFL, a fourth passivation layer PSV4, a first light conversion pattern CCP1, a low refractive layer LRL, and a color filter layer CFL.

The bank BNK may be disposed on the capping layer CPL. The bank BNK may have the second opening OP2 overlapping the first opening OP1. The bank BNK may include a light blocking material, to prevent light mixture between adjacent sub-pixels. In embodiments, the bank BNK may include an organic material. For example, the bank BNK may include an organic insulating material such as acrylic resin, epoxy resin, phenolic resin, polyamide resin, or polyimide resin.

The reflective layer RFL may be disposed on side surfaces of the bank BNK, which are adjacent to the second opening OP2. The reflective layer RFL may reflect incident light, and accordingly, light output efficiency may be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the capping layer CPL, the fourth passivation layer PSV4 may be disposed in the second opening OP2. The fourth passivation layer PSV4 may protect components disposed thereunder, and provide a flat surface. The fourth passivation layer PSV4 and any one of the first to third passivation layers PSV1, PSV2, and PSV3 may include the same material, but embodiments are not limited thereto.

On the fourth passivation layer PSV4, the first light conversion pattern CCP1 may be disposed in the second opening OP2.

The first light conversion pattern CCP1 may include color conversion particles and/or light scattering particles. The color conversion particles may convert incident light into light of another color by changing a wavelength of the incident light. For example, the color conversion particles may scatter incident light. In embodiments, the color conversion particles may be quantum dots. The light scattering particles may scatter incident light.

The first sub-pixel SP1 may be a red sub-pixel. In case that the first light emitting element LD1 emits light of a blue color, the first light conversion pattern CCP1 may include first color conversion particles QD1 that convert light of the blue color into light of a red color. In case that the first light emitting element LD1 emits light of the red color, the first light conversion pattern CCP1 may include light scattering particles. For example, the particles included in the first light conversion pattern CCP1 may be variously changed according to the first light emitting element LD1.

The low refractive layer LRL may be disposed on the bank BNK, the reflective layer RFL, and the first light conversion pattern CCP1. The low refractive layer LRL may have a refractive index lower than a refractive index of the first light conversion pattern CCP1. A first color filter CF1 may have a refractive index higher than the refractive index of the low refractive layer LRL. However, embodiments are not limited thereto, and the first color filter CF1 may have a refractive index lower than or equal to the refractive index of the low refractive layer LRL. The low refractive layer LRL may refract or totally reflect light according to an incident angle of the corresponding light. For example, the low refractive layer LRL may again provide light passing through the first light conversion pattern CCP1 to the first light conversion pattern CCP1. Accordingly, the light conversion efficiency of the first light conversion pattern CCP1 may be improved.

The color filter layer CFL may be disposed on the low refractive layer LRL. The color filter layer CFL may include the first color filter CF1 and light blocking patterns LBP. The first color filter CF1 may overlap the first light conversion pattern CCP1. The first color filter CF1 may allow light in a desired wavelength range to be selectively transmitted therethrough. In case that the first sub-pixel SP1 is a red sub-pixel, the first color filter CF1 may include a red color filter. The light blocking patterns LBP may include at least one of various kinds of light blocking materials.

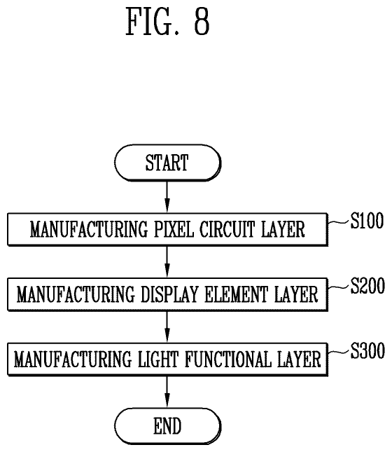

Hereinafter, a method of manufacturing a display device DD in accordance with an embodiment will be described with reference to FIGS. 8 to 19. In FIGS. 8 to 19, descriptions of portions overlapping the above-described portions will be simplified or will not be repeated.

FIG. 8 is a schematic flowchart illustrating a method of manufacturing a display device in accordance with an embodiment.

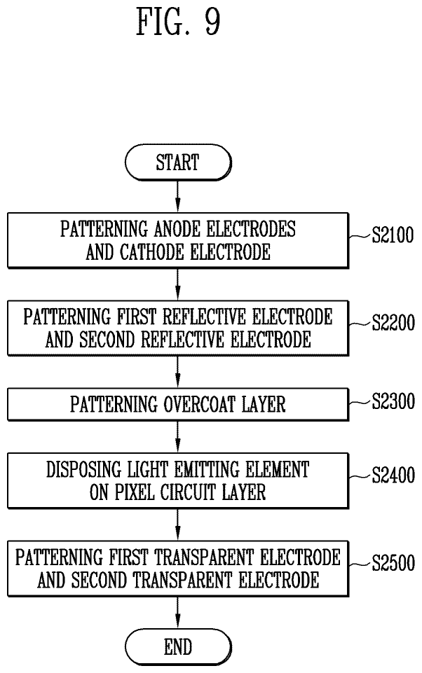

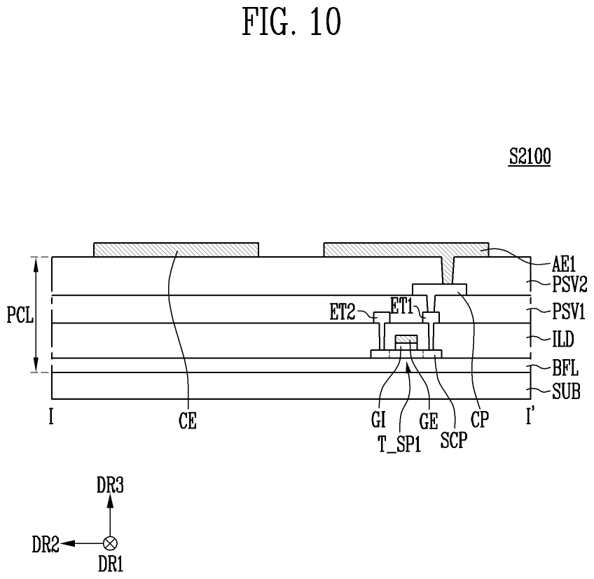

FIG. 9 is a schematic flowchart illustrating a step of manufacturing a display element layer in accordance with an embodiment. FIGS. 10 to 13 are schematic cross-sectional views illustrating process steps according to the step shown in FIG. 9. For convenience of description, FIGS. 10 to 13 schematically illustrate an area corresponding to the sectional structure described above with reference to FIGS. 6 and 7.

Referring to FIG. 8, the method of manufacturing the display device DD in accordance with the embodiment may include step S100 of manufacturing a pixel circuit layer, the step S200 of manufacturing a display element layer, and step S300 of manufacturing a light functional layer.

Referring to FIGS. 7 and 8, in the step S100 of manufacturing the pixel circuit layer, a pixel circuit layer PCL may be disposed on a substrate SUB.

In some embodiments, a conductive layer or an insulating layer on the substrate SUB may be formed based on an ordinary process for manufacturing a semiconductor device. For example, the conductive layer or the insulating layer on the substrate SUB may be formed through a photolithography process, be etched through various processes (e.g., wet etching, dry etching, and the like), and be deposited through various processes (e.g., sputtering, chemical vapor deposition, and the like). However, embodiments are not limited to a specific example.

In the step S100, a transistor T_SP1 may be patterned on the substrate SUB, and a buffer layer BFL, an interlayer insulating layer ILD, a first passivation layer PSV1, and a second passivation layer PSV2 may be formed.

Referring to FIG. 9, the step S200 of manufacturing the display element layer may include step S2100 of patterning anode electrodes and a cathode electrode, the step S2200 of patterning a first reflective electrode and a second reflective electrode, the step S2300 of patterning an overcoat layer, the step S2400 of disposing light emitting element on the pixel circuit layer, and step S2500 of patterning a first transparent electrode and a second transparent electrode.

Referring to FIGS. 9 and 10, in the step S2100 of patterning the anode electrodes and the cathode electrode, a first anode electrode AE1 and a cathode electrode CE may be formed on the pixel circuit layer PCL (or the substrate SUB). For example, in the step S2100, a second anode electrode and a third anode electrode may be formed.

In this step S2100, in case that the first anode electrode AE1 is formed, a contact hole penetrating the second passivation layer PSV2 may be formed. Accordingly, the first anode electrode AE1 may be electrically connected to the transistor T_SP1.

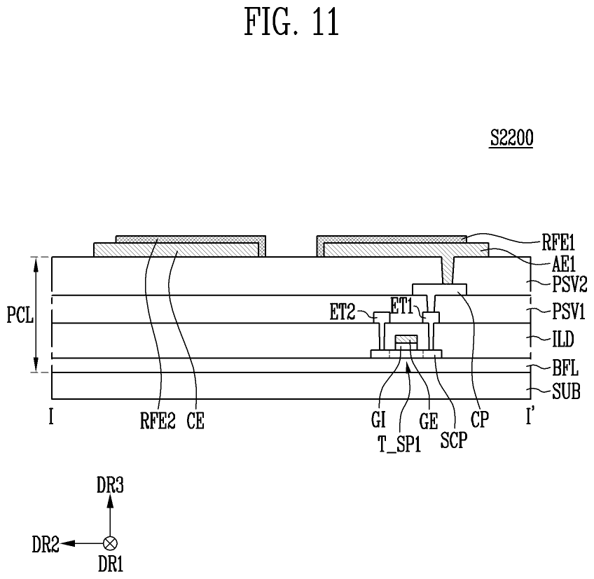

Referring to FIGS. 9 and 11, in the step S2200 of patterning the first reflective electrode and the second reflective electrode, the first reflective electrode RFE1 may be formed on the first anode electrode AE1, and the second reflective electrode RFE2 may be formed on the cathode electrode CE.

For example, the first reflective electrode RFE1 may be formed on a side surface of the first anode electrode AE1, and the second reflective electrode RFE2 may be formed on a side surface of the cathode electrode CE. The first reflective electrode RFE1 and the second reflective electrode RFE2 may be spaced apart from each other in the second direction DR2.

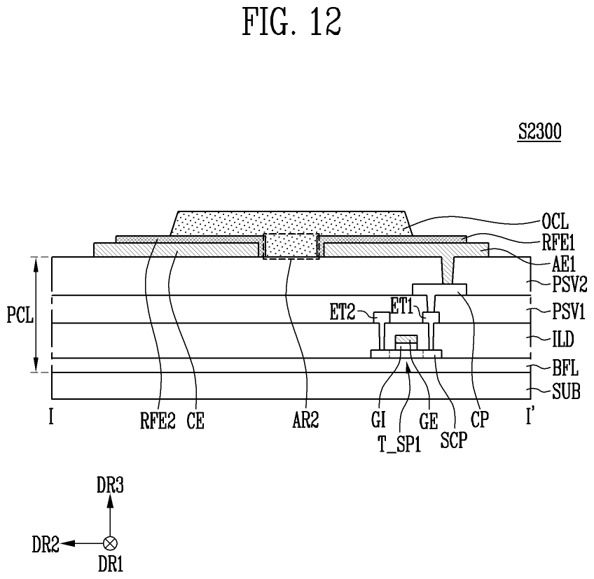

Referring to FIGS. 9 and 12, in the step S2300 of patterning the overcoat layer, an overcoat layer OCL may be formed on the first reflective electrode RFE1 and the second reflective electrode RFE2.

In some embodiments, the overcoat layer OCL may be formed on the pixel circuit layer PCL (or the substrate SUB), based on a process such as deposition. In an example, after the overcoat layer OCL is formed, an additional etching process may be performed on the overcoat layer OCL. This will be described in more detail later together with FIG. 19.

The overcoat layer OCL may be disposed to overlap a portion of the first anode electrode AE1 and a portion of the cathode electrode CE. For example, the overcoat layer OCL may be disposed to include an area AR2 in which the overcoat layer OCL does not overlap both the first anode electrode AE1 and the cathode electrode CE. In the area AR2, the overcoat layer OCL may be in contact with the pixel circuit layer PCL. For example, the overcoat layer OCL may be in contact with the second passivation layer PSV2 in the area AR2.

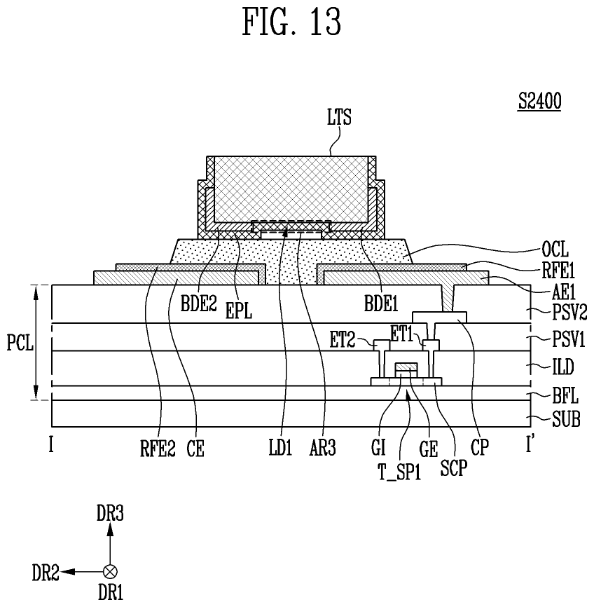

Referring to FIGS. 9 and 13, in the step S2400 of disposing the light emitting element on the pixel circuit layer, a first light emitting element LD1 including first and second element electrodes BDE1 and BDE2 and a protective layer EPL may be disposed on the pixel circuit layer PCL.

In an embodiment, the first light emitting element LD1 may be disposed on the overcoat layer OCL. The first light emitting element LD1 may include the first and second element electrodes BDE1 and BDE2 and the protective layer EPL.

The first light emitting element LD1 may be disposed such that the first element electrode BDE1 may be adjacent to the first anode electrode AE1 and the second element electrode BDE2 may be adjacent to the cathode electrode CE. The first and second element electrodes BDE1 and BDE2 may be spaced apart from each other along the second direction DR2.

The protective layer EPL may be formed along side surfaces of the first light emitting element LD1 and a bottom surface (or lower surface) of the first light emitting element LD1, except a top surface (or upper surface) LTS of the first light emitting element LD1. For example, the protective layer EPL may be disposed to surround the first and second element electrodes BDE1 and BDE2. Accordingly, the protective layer EPL may be disposed in an area AR3 in which the first and second element electrodes BDE1 and BDE2 are spaced apart from each other along the second direction DR2.

The protective layer EPL may be in contact with the overcoat layer OCL in an area in which the first and second element electrodes BDE1 and BDE2 overlap each other, and be spaced apart from the overcoat layer OCL in the area AR3 in which the first and second element electrodes BDE1 and BDE2 are spaced apart from each other along the second direction DR2.

The protective layer EPL may include a material identical to the material which the first and second protective electrodes EPL1 and EPL2 (see FIG. 7) include.

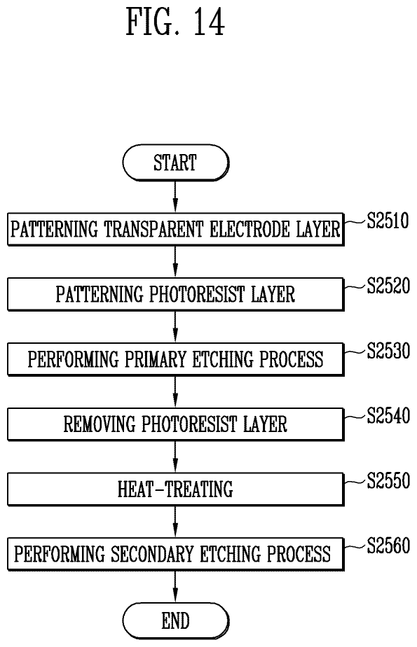

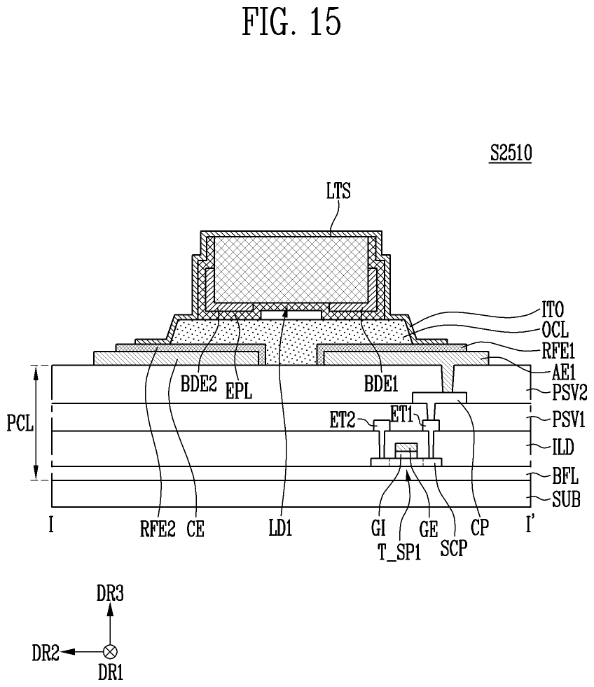

FIG. 14 is a schematic flowchart illustrating a step of manufacturing first and second transparent electrodes in accordance with an embodiment. FIGS. 15 to 19 are schematic cross-sectional views illustrating process steps according to the step shown in FIG. 14. For convenience of description, FIGS. 15 to 19 schematically illustrate an area corresponding to the sectional structure described above with reference to FIGS. 6 and 7.

Referring to FIGS. 9 and 14, the step S2500 of patterning the first transparent electrode and the second transparent electrode may include step S2510 of disposing a transparent electrode layer, the step S2520 of patterning a photoresist layer, the step S2530 of performing a primary etching process, the step S2540 of removing the photoresist layer, the step S2550 of heat-treating, and step S2560 of performing a secondary etching process. Referring to FIGS. 14 and 15, in the step S2510 of disposing a transparent electrode layer, a transparent electrode layer ITO may be disposed on the first anode electrode AE1, the cathode electrode CE, and the first light emitting element LD1.

For example, the transparent electrode layer ITO may be disposed at an exposed top surface (or exposed upper surface) of the first anode electrode AE1, an exposed portion of the first reflective electrode RFE1, an exposed portion of the overcoat layer OCL, an exposed portion of the protective layer EPL, the top surface (or upper surface) LTS of the first light emitting element LD1, an exposed portion of the second reflective electrode RFE2, and an exposed top surface (or exposed upper surface) of the cathode electrode CE.

In embodiments, the transparent electrode layer ITO may be disposed on the first anode electrode AE1, the cathode electrode CE, and the first light emitting element LD1 through a deposition process.

The transparent electrode layer ITO may include a material identical to the material in which the first and second transparent electrodes ITO1 and ITO2 (see FIG. 7) include.

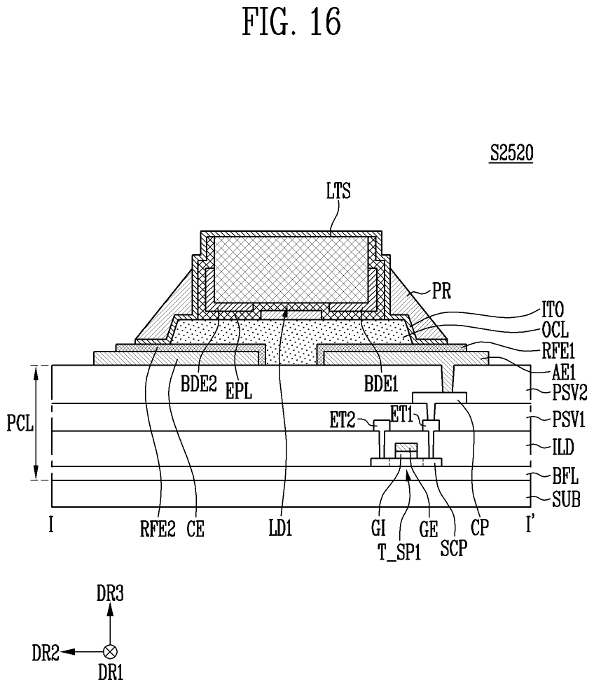

Referring to FIGS. 14 and 16, in the step S2520 of patterning the photoresist layer, a photoresist layer PR may be patterned on the transparent electrode layer ITO. For example, the photoresist layer PR may be patterned in the area AR3 in which the protective layer EPL is spaced apart from the overcoat layer OCL.

The area of the photoresist layer PR disposed on the transparent electrode layer ITO may overlap the area of the first transparent electrode ITO1 (see FIG. 7) and the area of the second transparent electrode ITO2 (see FIG. 7), which are to be manufactured.

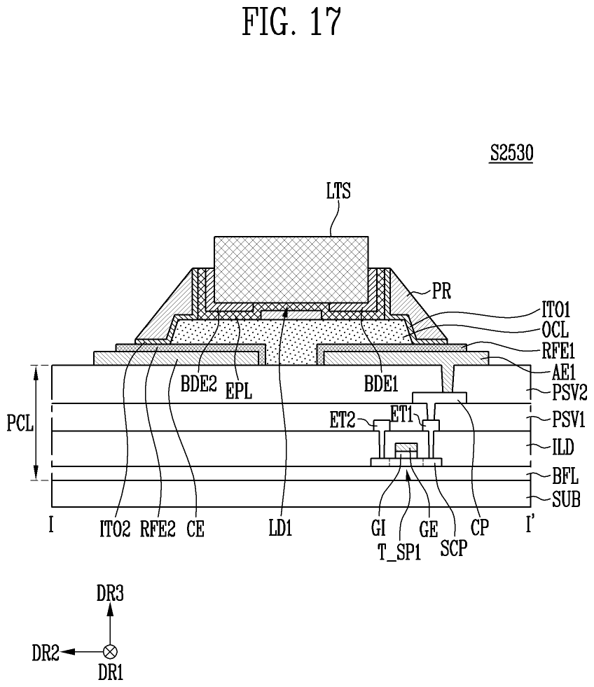

Referring to FIGS. 14 and 17, in the step S2530 of performing the primary etching process, a first transparent electrode ITO1 and a second transparent electrode ITO2 may be provided as the transparent electrode layer ITO is etched using the photoresist layer PR as an etching mask. For example, the protective layer EPL along with the transparent electrode layer ITO may also be etched according to a pattern of the photoresist layer PR.

In an embodiment, the transparent electrode layer ITO and the protective layer EPL may be etched based on a wet etching process.

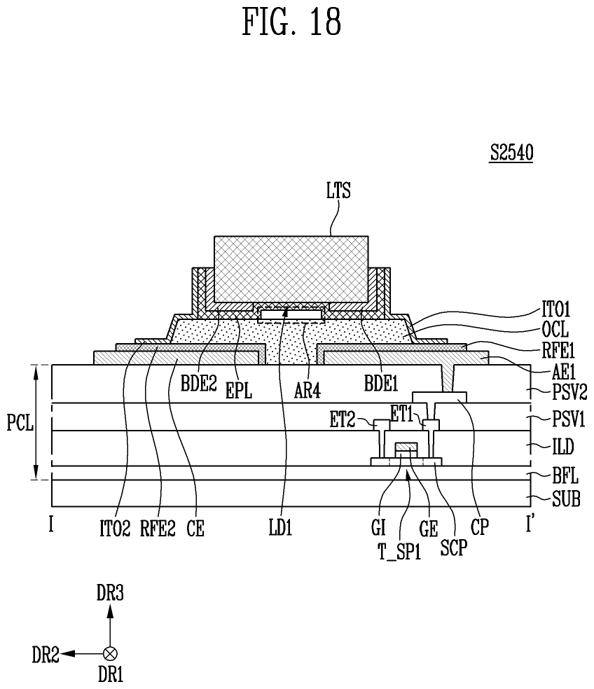

Referring to FIGS. 14 and 18, in the step S2540 of removing the photoresist layer, the photoresist layer PR may be removed. For example, after the first and second transparent electrodes ITO1 and ITO2 are manufactured, the photoresist layer PR may be removed.

As the photoresist layer PR is removed, an area AR4 may be provided, in which the protective layer EPL and the overcoat layer OCL are spaced apart from each other.

For example, after the photoresist layer PR is removed, the step S2550 of heat-treating may be performed. In the step S2550, the first and second transparent electrodes ITO1 and ITO2 may be crystallized. A heat-treatment temperature may be determined within a range in which the first and second transparent electrodes ITO1 and ITO2 are crystallized and the protective layer EPL is not crystallized. For example, although heat treatment is performed, the protective layer EPL is not crystallized but may maintain amorphous characteristics.

Accordingly, although the secondary etching process is performed in the subsequent step S2560, the crystallized first and second transparent electrodes ITO1 and ITO2 are not etched, but only the protective layer EPL may be etched.

Referring to FIGS. 14, 18, and 19, in the step S2560 of performing the secondary etching process, the protective layer EPL may be etched except a portion of the protective layer EPL, which is surrounded by the heat-treated first and second transparent electrodes ITO1 and ITO2.

More specifically, as the protective layer EPL is etched in the area AR3 in which the protective layer EPL while being spaced apart from the overcoat layer OCL, a first protective electrode EPL1 and a second protective electrode EPL2 may be provided.

For example, as the protective layer EPL is etched in an area AR4, an area AR1 may be provided, in which the second element electrode BDE2 and the second protective electrode EPL2 are not in contact with each other.

In the step S2560, as the non-heat-treated protective layer EPL is etched and the heat-treated first and second transparent electrodes ITO1 and ITO2 are not etched, a height H1 of the first protective electrode EPL1 may be smaller than a height H2 of the first transparent electrode ITO1 in a cross-sectional view. Each of the height H1 of the first protective electrode EPL1 and the height H2 of the first transparent electrode ITO1 may be a height with respect to the overcoat layer OCL in a cross-sectional view.

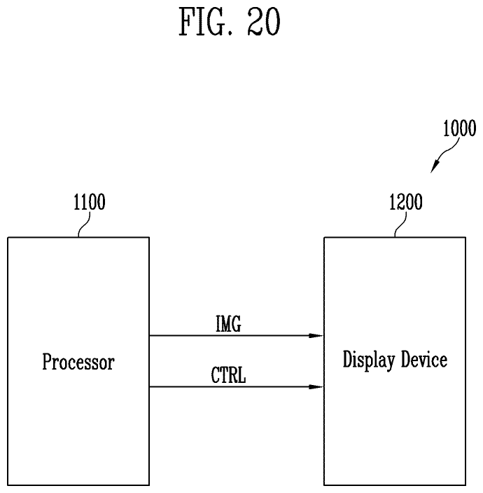

FIG. 20 is a block diagram illustrating an embodiment of a display system or an electronic device.

Referring to FIG. 20, the display system (or electronic device) 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

The processor 1100 may transmit image data IMG and a control signal CTRL to the display device 1200. The display device 1200 may display an image, based on the image data IMG and the control signal CTRL. The display device 1200 may be formed identical to the display device DD described with reference to FIG. 1. The image data IMG and the control signal CTRL may be provided as the input image data IMG and the control signal CTRL, which are shown in FIG. 1, respectively.

The display system (or electronic device) 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

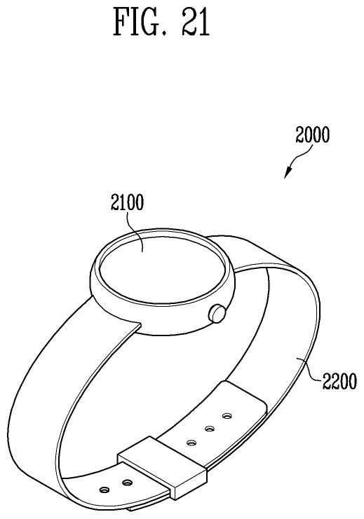

FIGS. 21 to 24 are schematic perspective views illustrating application examples of the display system shown in FIG. 20.

Referring to FIG. 21, the display system 1000 shown in FIG. 20 may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The display system 1000 and/or the display device 1200 may be applied to the display part 2100, so that image data including time information may be provided to the user.

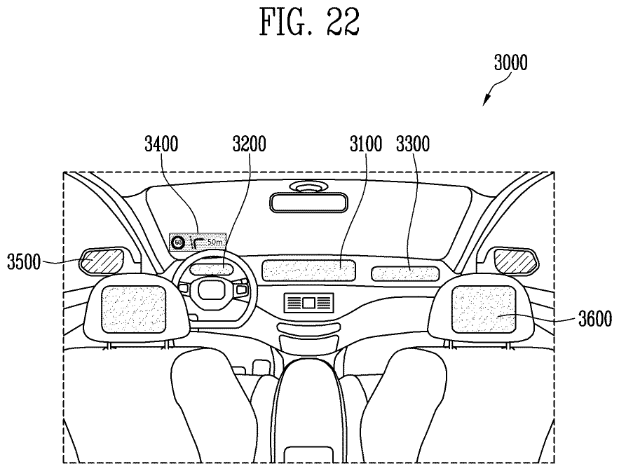

Referring to FIG. 22, the display system 1000 shown in FIG. 20 may be applied to an automotive display system 3000. The automotive display system 3000 may include a computing system provided at the inside/outside of a vehicle to provide image data.

For example, the display system 1000 and/or the display device 1200 may be applied to at least one of an infortainment panel 3100, a cluster 3200, a co-driver display 3300, a head-up display 3400, a side mirror display 3500, and a rear seat display 3600, which are provided in the vehicle.

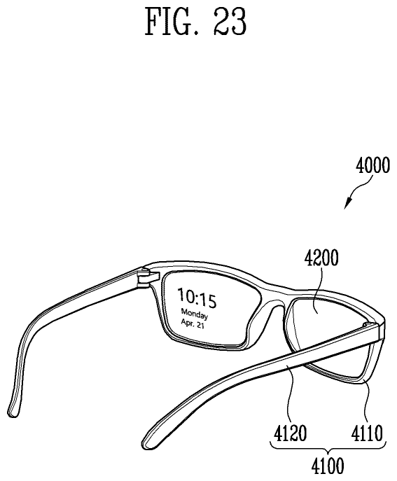

Referring to FIG. 23, the display system 1000 shown in FIG. 20 may be applied to smart glasses 4000. The smart glasses 4000 may be a wearable electronic device which is worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. For example, a projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, transparent synthetic resin, and the like.

In order to enable eyes of the user to recognize visual information, the lens part 4200 may allow an image caused by a light signal transmitted from the projector of the frame 4100 to be reflected by a rear surface (e.g., a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

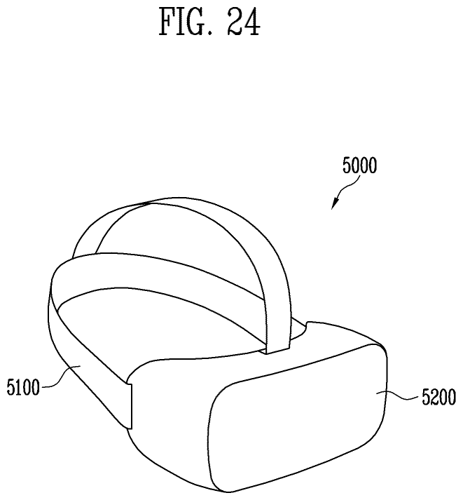

Referring to FIG. 24, the display system 1000 shown in FIG. 20 may be applied to a head mounted display device 5000.

The head mounted display device 5000 may be a wearable electronic device which is worn on the head of a user. For example, the head mounted display device 5000 may be a wearable device for virtual reality (VR) or mixed reality (MR).

The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may surround a side portion of the head of the user, and the vertical band may surround an upper portion of the head of the user. However, embodiments are not limited thereto. For example, the head mounted band 5100 may be implemented in the form of a glasses frame, a helmet or the like.

The display device accommodating case 5200 may accommodate the display system 1000 and/or the display device 1200.

In other embodiments, the display system 1000 shown in FIG. 16 may be applied to, a mobile phone, a smartphone, a portable computer, a tablet personal computer (PC), a watch phone, a portable multimedia player (PMP), a navigation system, an ultra-mobile computer (UMPC), a virtual reality (VR) device, a mixed reality (MR) device, and an augmented reality (AR) device.

In the display device in accordance with the disclosure, damage of electrodes of the light emitting element can be prevented, the light emission efficiency of the light emitting element can be improved, and manufacturing cost of the light emitting element can be reduced.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate; and
a display element layer disposed on the substrate,
wherein the display element layer includes:
an anode electrode and a cathode electrode;
a first reflective electrode disposed on the anode electrode;
a second reflective electrode disposed on the cathode electrode;
a light emitting element including a first protective electrode, a second protective electrode, a first element electrode disposed at an inner side of the first protective electrode, and a second element electrode disposed at an inner side of the second protective electrode;
a first transparent electrode electrically connecting the first reflective electrode to the first protective electrode; and
a second transparent electrode electrically connecting the second reflective electrode to the second protective electrode.

2. The display device of claim 1, wherein
the first element electrode is formed at side surfaces adjacent to the anode electrode among side surfaces of the light emitting element and a portion of a lower surface of the light emitting element, which is adjacent to the anode electrode, and
the second element electrode is formed at side surfaces adjacent to the cathode electrode among the side surfaces of the light emitting element and a portion of the lower surface of the light emitting element, which is adjacent to the cathode electrode.

3. The display device of claim 1, wherein the first element electrode and the second element electrode have a clamp shape.

4. The display device of claim 1, wherein
the first protective electrode is formed along side surfaces of the first element electrode and a lower surface of the first element electrode, and
the second protective electrode is formed along side surfaces of the second element electrode and a lower surface of the second element electrode.

5. The display device of claim 1, wherein the first protective electrode and the second protective electrode have a clamp shape.

6. The display device of claim 1, wherein
the first element electrode and the second element electrode include a same reflective conductive material, and
the first protective electrode and the second protective electrode include a same conductive material.

7. The display device of claim 6, wherein
the first element electrode and the second element electrode include at least one of aluminum and titanium, and
the first protective electrode and the second protective electrode include indium zinc oxide.

8. The display device of claim 7, wherein the first transparent electrode and the second transparent electrode include a same transparent conductive material.

9. The display device of claim 1, wherein
the display element layer further includes an overcoat layer partially covering the first reflective electrode and the second reflective electrode,
the light emitting element is disposed on the overcoat layer,
in a cross-sectional view, a height of the first protective electrode is smaller than a height of the first transparent electrode, and
each of the height of the first protective electrode and the height of the first transparent electrode is a height with respect to the overcoat layer in a cross-sectional view.

10. The display device of claim 1, wherein
the display element layer further includes an overcoat layer partially covering the first reflective electrode and the second reflective electrode,
the light emitting element is disposed on the overcoat layer, and
in a cross-sectional view, an area in which the first element electrode is not in contact with the first protective electrode is provided under the first element electrode.

11. A method of manufacturing a display device, the method comprising:
manufacturing a pixel circuit layer disposed on a substrate; and
manufacturing a display element layer on the pixel circuit layer, wherein
the manufacturing of the display element layer includes:
patterning an anode electrode and a cathode electrode on the pixel circuit layer;
patterning a first reflective electrode electrically connected to the anode electrode and a second reflective electrode electrically connected to the cathode electrode;
patterning an overcoat layer on the first reflective electrode and the second reflective electrode; and
disposing, on the pixel circuit layer, a light emitting element including a protective layer, a first element electrode, and a second element electrode, and
the protective layer is formed along side surfaces of the light emitting element and a lower surface of the light emitting element, and surrounds the first element electrode and the second element electrode.

12. The method of claim 11, wherein the manufacturing of the display element layer further includes patterning a transparent electrode layer on the anode electrode, the first reflective electrode, the cathode electrode, the second reflective electrode, the overcoat layer, and the light emitting element.

13. The method of claim 12, wherein the manufacturing of the display element layer further includes patterning a photoresist layer on the transparent electrode layer.

14. The method of claim 13, wherein the manufacturing of the display element layer further includes:
etching the transparent electrode layer and the protective layer, using the photoresist layer as an etching mask;
providing the etched transparent electrode layer as a first transparent electrode and a second transparent electrode; and
removing the photoresist layer.

15. The method of claim 14, wherein
the manufacturing of the display element layer further includes heat-treating in the display element layer, and
a heat-treatment temperature is determined within a range in which the first and second transparent electrodes are crystallized and the protective layer is not crystallized.

16. The method of claim 15, wherein the manufacturing of the display element layer further includes:
etching the protective layer except a portion of the protective layer, which is surrounded by the heat-treated first and second transparent electrodes; and
providing the etched protective layer as a first protective electrode and a second protective electrode.

17. The method of claim 16, wherein the first protective electrode and the second protective electrode have a clamp shape.

18. The method of claim 17, wherein
the first element electrode and the second element electrode include a same reflective conductive material, and
the first protective electrode and the second protective electrode include a same conductive material.

19. The method of claim 18, wherein
the first element electrode and the second element electrode include at least one of aluminum and titanium, and
the first protective electrode and the second protective electrode include indium zinc oxide, wherein
the first transparent electrode and the second transparent electrode include a same transparent conductive material.

20. An electronic device comprising:
a display device including a display element layer disposed on a substrate,
wherein the display element layer includes:
an anode electrode and a cathode electrode;
a first reflective electrode disposed on the anode electrode;
a second reflective electrode disposed on the cathode electrode;
a light emitting element including a first semiconductor layer, a second semiconductor layer, and an insulative film;
a first transparent electrode directly electrically connecting the second semiconductor layer to the first reflective electrode; and
a second transparent electrode directly electrically connecting the first semiconductor layer to the second reflective electrode.
